(19) United States
(12) Patent Application Publication
(10) Pub. No.: US 2003/0046630 A1
(43) Pub. Date: Mar. 6, 2003

(54) Memory using error-correcting codes to correct stored data in background

(76) Inventor: Mark Hilbert, Warrenville, IL (US)

Correspondence Address: The Law Offices of Calvin B. Ward, Suite 305, 18 Crow Canyon Court, San Ramon, CA, 94583, US

(21) Appl. No.: 09/947,320

(22) Filed: Sep. 5, 2001

(51) Int. Cl. G11C 29/00; G06F 13/00

(52) U.S. Cl. 714/763; 711/105

(57) ABSTRACT

A memory that corrects storage errors during those periods in which the memory is not servicing read/write instructions from an external system. The memory reads and writes data words that are stored in a storage block that includes a plurality of storage words. Each storage word stores a data entry specifying one of the data words. The data entry is encoded with error-correcting information sufficient to correct a one-bit error in the data word. The storage words are connected to the error-correcting circuit during idle periods or during the conventional refresh operations in the case of DRAM-like memories. The controller also causes each corrected storage word to be re-written to the storage block in place of the storage word from which the corrected storage word was generated if an error is detected by the error-correcting circuitry.

### FIELD OF THE INVENTION

The present invention relates to computer memories and the like, and more particularly, to a memory system that uses error-correcting codes (ECCS) to correct erroneous data in the background.

### BACKGROUND OF THE INVENTION

An error correcting code will be defined to be a transformation that maps each possible value of a data word onto a corresponding value in a set of storage words such that errors in storage can be detected and corrected. In general, these codes rely on the fact that only a small number of the possible storage words will be used if no errors are introduced during the storage and retrieval process. For example, in a typical error-correcting code, each 8-bit data word is transformed into a 16-bit storage word. There are only 256 possible data word values; hence, only 256 of the possible 65536 storage word values will be used in the absence of errors. When an error occurs, a valid storage word is usually converted to an invalid storage word. The error correcting system then tries to figure out which valid state would have given rise to the detected invalid state if various numbers of bits were altered by the storage operation.

The ability of an error correcting code to correct errors is measured by a quantity referred to as the “Hamming Distance” associated with the code. For example, codes with a Hamming Distance of 5 can detect errors resulting from 4 single-bit errors and correct for all possible 2 single-bit errors. A discussion of error correcting codes may be found in ERROR CORRECTING CODES, 2ND EDITION, by Peterson and Weldon, MIT PRESS, 1972, or in PRACTICAL ERROR DESIGN FOR ENGINEERS, by Neil Glover, Data Systems Technology Corp., 1982.

As the storage capacity of memory systems increases, the probability that an error will be introduced into the data stored in the memory increases for a number of reasons. Increases in memory size are typically achieved by reducing the size of the individual memory cells as fabrication processes utilizing ever-decreasing feature sizes are introduced. Consider a DRAM. Data is stored by storing a charge on a capacitor. As the size of the capacitor decreases, the amount of charge stored decreases. During storage, the charge slowly leaks off of the capacitor, and hence, the data is refreshed periodically. If a capacitor has a small leakage path that becomes significant when the part heats up or develops after the device has been tested, the charge may be lost before the data is refreshed. The probability of such a leak developing increases as the thickness of the dielectric in the capacitor decreases. Errors from leakage increase with decreasing feature size. Similarly, small charges are more likely to be altered by cosmic rays or other background radiation.

Memory systems that utilize ECCs to correct data storage errors are known to the art. In such systems, the data word that is to be stored and retrieved is augmented with a number of error correcting bits to provide the storage word. These error-correcting bits are computed at the time the word is sent to the memory for storage. When the word is retrieved at some later point in time, the ECC is used to correct any errors that have occurred during the storage of the data in the memory.

These systems only correct the data when the data is read. If the time period between writing the data to the memory and the subsequent read is long, errors can accumulate in the stored data. If sufficient errors accumulate, the ECC will no longer be able to correct the errors.

These prior art systems also provide limited data on which to predict memory failures prior to the memory actually failing. Memory systems in which the memory includes a controller that tracks errors based on ECC codes and reconfigures the memory to eliminate bad memory blocks are described in U.S. Pat. No. 6,236,602 to Patti. In this type of system, the controller depends on the ECC data to determine that memory cells are starting to fail, i.e., has a high error rate. However, the data obtained depends on the rate at which each word is read as well as the error rate in the storage block in which that word is stored. If the program currently running reads data repeatedly from a particular memory block, even a small error rate in that block will generate a number of errors leading to the block being replaced. However, a block having a much higher error rate, but only read infrequently, will generate very few errors.

Broadly, it is the object of the present invention to provide an improved ECC memory.

These and other objects of the present invention will become apparent to those skilled in the art from the following detailed description of the invention and the accompanying drawings.

### SUMMARY OF THE INVENTION

The present invention is a memory that includes an interface circuit for receiving and sending data words to an external system in response to storage commands received from the external system specifying an address. The data words are stored in a storage block that includes a plurality of storage words. Each storage word stores a data entry specifying one of the data words. The data entry is encoded with error-correcting information sufficient to correct a one-bit error in the data word. The memory also includes an error-correcting circuit for generating a corrected storage word from one of the storage words coupled thereto utilizing the error-correcting information. The error-correcting circuit generates an error signal indicating that the corrected storage word differs from the coupled storage word. The storage words are connected to the error-correcting circuit by an interface that allows the corrected storage word to be rewritten to the storage block. A controller accesses each of the storage words independent of the received addresses and causes the error-correcting circuit to generate the corrected storage word from that storage word. The controller accesses the storage words during time periods in which the memory is not responding to the storage commands. The controller also causes each corrected storage word to be re-written to the storage block in place of the storage word from which the corrected storage word was generated if the error signal was generated. In one embodiment of the invention, the storage block includes a DRAM having a plurality of memory blocks. Each memory block includes a plurality of single bit storage cells organized as a plurality of rows and columns of single bit storage cells, each of the single bit storage cells in one of the rows being coupled to a bit line corresponding to the column in which said single bit storage cell is located. A row select circuit causes each single bit storage cell in one of the rows to be coupled to the bit lines. Each bit line is connected to a sense amplifier for reading a data value on that bit line. A multiplexer selects one bit line at a time from the storage block in response to a column address signal coupled to the multiplexer, the multiplexer connecting the selected bit line to the error-correcting circuit. The controller provides the column address to the multiplexers during the background error-correction operation. The background error-correcting operation can be combined with the normal DRAM refresh cycle. In such embodiments, the controller includes a refresh circuit for operating the row select circuits, and the sense amplifiers to rewrite each value on the bit lines into the single bit storage cells in one of the selected rows. The corrected storage word replaces the values on the bit lines corresponding to the bits of the corresponding storage word currently coupled to the error-correcting circuit if the error signal was generated. In another embodiment of the invention, the controller delays the rewriting of the data bits in a row if the error signal was generated, thereby providing additional time for the rewrite operation.

### BRIEF DESCRIPTION OF THE DRAWINGS

FIG. 1 is a block diagram of a memory block 10 according to one embodiment of the present invention.

FIG. 2 is a block diagram of a memory 60 constructed from N_{T} storage blocks of the type shown in FIG. 1.

### DETAILED DESCRIPTION OF THE PREFERRED EMBODIMENTS OF THE INVENTION

To simplify the following discussion, the present invention will be explained in terms of a DRAM architecture. The manner in which the present invention is applied to other memory architectures will then be discussed in more detail.

It will be assumed that the memory is designed to store and retrieve N-bit data words to which N_{E} error-correction bits have been added to provide a storage word having N_{T}=N+N_{E} bits. In the following discussion, the i^{th} bit of the j^{th} storage word stored in the memory will be denoted by ^{j}Wⱼ. To simplify the following discussion, it will be assumed that the memory is divided into blocks of memory cells in which each block is organized as a plurality of rows and columns of memory cells. Further, it will be assumed that each block of memory cells stores data for one particular bit position of the storage words assigned to that block. In this case, a storage word is read by reading one bit from each of N_{T} memory blocks. The specific bit is determined by the address of the data word, i.e., the value of j defined above. The value of i and the value of the most significant bits of the address determine the block. The remaining bits in the address may be viewed as defining a row address and a column address, the memory cell in question being located at the intersection of the defined row and column.

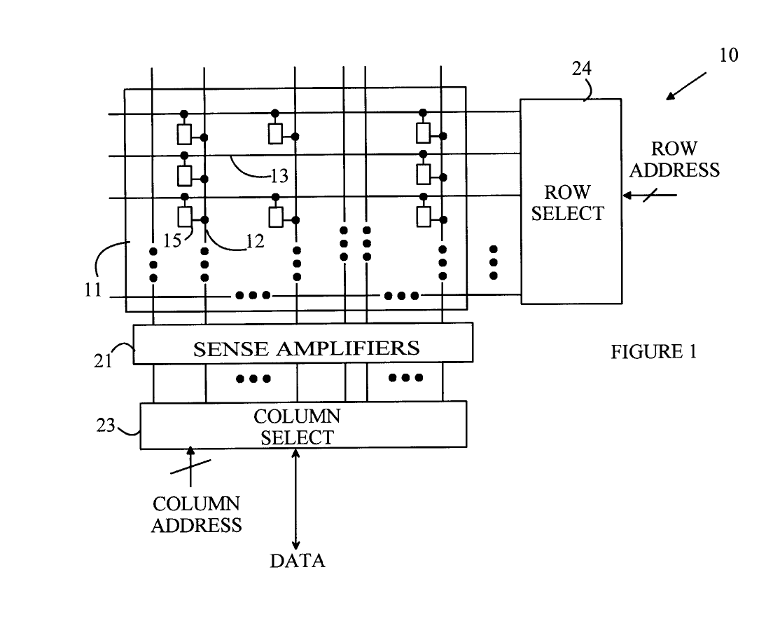

Refer now to FIG. 1, which is a block diagram of a memory block 10 according to one embodiment of the present invention. Memory block 10 includes an array of data storage cells 11 organized as a plurality of rows and columns. A typical storage cell is shown at 15. A storage cell is selected for reading or writing by placing a signal on the row line connected to that storage cell. A typical row line is shown at 13. All of the storage cells on a given row line are selected together. When selected, each storage cell on the selected row line places a signal indicative of the data stored therein on the bit line connected to that storage cell. A typical bit line is shown at 12. The specific row selected is determined by the row portion of the address communicated to the memory by the device seeking to read data and by a row mapping that is stored in row select circuit 24.

All of the data values on the selected row line are read in parallel. A block of sense amplifiers 21 reads the signals on the bit lines and latches their values. A column select circuit 23 is used to select the value from one of the bit lines for output. The specific bit line selected is determined by the column portion of the address and by a column mapping that is stored in the column select circuit 23.

A new data bit is written into memory block 10 by providing the address at which the data is to be stored. The row containing this address is read out, and the data values currently in that row are refreshed by the sense amplifiers. The new data bit value is written into the bit line selected by the column address, overriding the value in the sense amp. The entire row of storage cells is then re-written from the register in the sense amplifier block.

When the memory is refreshed, each row is read in sequence. The values latched in the sense amplifiers are re-written back to the row as discussed above.

Refer now to FIG. 2, which is a block diagram of a memory 60 constructed from N_{T} storage blocks of the type shown in FIG. 1. As noted above, each block stores bits for a particular position in the data words stored in the memory. Hence, each of the ECC bits for a particular ECC bit position is stored in a memory block such as memory block 62, and each data bit for a particular data bit position, i.e., column, is stored in a memory block such as memory block 61. A particular bit is selected by controller 65 by applying a row select signal to the memory blocks and then applying a bit select signal to the multiplexers shown at 63. During a read or write operation, controller 65 generates the column and row addresses from the addresses supplied to the controller as part of the operation in question.

During a refresh cycle in a conventional DRAM, the column address is not used, since no data is read to or from the multiplexers in prior art memories. The present invention, in contrast, treats each row refresh as if it were a write operation with the data being generated by the ECC circuit 64. Controller 65 sets the specific column address used in the refresh operation such that the column address cycles through each of the possible column addresses during the various refresh cycles. In the preferred embodiment of the present invention, the column address is incremented at the end of each complete refresh cycle; however, other algorithms may be utilized. Thus, on each row refresh cycle, one of the possible data words stored in that row is routed to the ECC circuit as if the data was being read followed by a write operation. The ECC circuit then computes a corrected data word using the ECC bits of that word and writes the corrected data word back to the memory blocks in time for the data to be latched in the appropriate latches of the sense amplifier blocks prior to the data bits being rewritten to the memory blocks.

It should be noted that the timing constraints can be relaxed significantly without markedly increasing the refresh cycle times. Denote the time needed to read out a row and read the data back into the row without waiting for external data as a “refresh period”. Denote the time needed by the ECC circuitry to detect an error by the “ECC error detection time”, and the time to read the data, detect an error, and generate the corrected data word by the “ECC cycle time”. The refresh period may be significantly shorter than the read time for the memory, since a refresh operation does not involve moving the data on or off of the chip. In fact, the data need only move a short distance on the chip during a refresh. In general, the chip will be designed such that the ECC cycle time is the same as the read cycle during normal data read/write operations. Hence, the time needed to compute a corrected data word may be much greater than a refresh period. In such embodiments, the present invention does not lengthen the refresh period to accommodate the ECC circuitry delay.

The fraction of time that the ECC circuitry finds an error in a word is expected to be very small. Hence, very little is lost by increasing the refresh cycle time in those cases. In such embodiments of the present invention, the ECC circuitry signals the controller when it finds an error, i.e., new data must be written back into the word. In this case, the controller holds the row address constant for a time that is sufficient for the ECC circuitry to write the data back into the word. That is, the controller lengthens that refresh cycle to a value sufficient to allow the data to be corrected. The controller can then return to normal refresh cycle timing.

The above-described embodiments of the present invention have been based on DRAM memory designs. Such memories are particularly well suited to background error corrections since these memories already include refresh circuitry and controllers. However, the present invention may be utilized with other memory architectures by adding a background “refresh” process that cycles through the memory locations when memory is not providing data to an external processor.

It should be noted that a memory according to the present invention removes errors in the background. Hence, the number of errors that are expected at an external read operation is greatly reduced, if not eliminated, since only errors that have occurred since the last sweep of the memory will be present. Accordingly, in one embodiment of a memory according to the present invention, the ECC bits are ignored during an external read. This allows the data to be delivered to the processor that sent the read command without delaying the data delivery while the ECC circuit checks the data.

Various modifications to the present invention will become apparent to those skilled in the art from the foregoing description and accompanying drawings. Accordingly, the present invention is to be limited solely by the scope of the following claims.

What is claimed is:

1. A memory comprising:
an interface circuit for receiving and sending data words to an external system in response to storage commands received from said external system, said commands specifying an address;
a storage block comprising a plurality of storage words, each storage word storing a data entry specifying one of said data words, said data entry being encoded with error-correcting information sufficient to correct a one-bit error in said data word;
an error-correcting circuit for generating a corrected storage word from one of said storage words coupled thereto utilizing said error-correcting information, said error-correcting circuit generating an error signal indicating that said corrected storage word differs from said coupled storage word;
an interface for connecting each storage word to said error-correcting circuit and for rewriting said storage word with said corrected storage word; and
a controller for accessing each of said storage words independent of said received addresses and causing said error-correcting circuit to generate said corrected storage word from that storage word, said controller accessing said storage words during time periods in which said memory is not responding to said storage commands, wherein said controller also causes each corrected storage word to be re-written to said storage block in place of said storage word from which said corrected storage word was generated if said error signal was generated.

2. The memory of claim 1 wherein said controller repetitively cycles through all of said storage words in a predetermined order to correct errors in said data words.

3. The memory of claim 1 wherein said storage block comprises a DRAM comprising:
a plurality of memory blocks, each memory block comprising a plurality of single bit storage cells organized as a plurality of rows and columns of single bit storage cells, all of said single bit storage cells in one of said rows being coupled to a bit line corresponding to said row, there being one such bit line for each column;
a row select circuit for causing each single bit storage cell in one of said rows to be coupled to said bit lines;
a plurality of sense amplifiers, each sense amplifier reading a data value on a corresponding one of said bit lines; and
a multiplexer for selecting one of said bit lines at a time from the storage block in response to a column address signal being coupled to said multiplexer, said multiplexer connecting said selected bit line to said error-correcting circuit,
said controller provides said column address to said multiplexers.

4. The memory of claim 3 wherein said controller further comprises a refresh circuit for operating said row select circuits and said sense amplifiers to rewrite each value on said bit lines into said single bit storage cells in one of said selected rows, and wherein said corrected storage word replaces said values on said bit lines corresponding to said bits of said corresponding storage word currently coupled to said error-correcting circuit if said error signal was generated.

5. The memory of claim 4 wherein said controller delays said rewrite if said error signal was generated.
